(19) United States
(12) Patent Application Publication
(10) Pub. No.: US 2026/0050024 A1
(43) Pub. Date: Feb. 19, 2026

(54) Liquid Load Banks

(71) Applicant: Liquid LB LLC, Austin, TX (US)

(72) Inventor: David Christopher Starr, Austin, TX (US)

(21) Appl. No.: 19/298,687

(22) Filed: Aug. 13, 2025

Related U.S. Application Data
(60) Provisional application No. 63/682,686, filed on Aug. 13, 2024.

(51) Int. Cl. G01R 31/00; G01R 31/40; H01C 1/08; H01C 1/16

(52) U.S. Cl. CPC G01R 31/003; G01R 31/40; H01C 1/08; H01C 1/16

(57) ABSTRACT

A liquid-cooled load bank contains electrical and mechanical load cells to test and validate an electrical system with an electrical load and a mechanical system by heating a testing fluid in a circulation heater in the mechanical load cell and cooling of the mechanical load cell with the mechanical system in a building to validate the electrical system and the mechanical system of the building during a commissioning of the building. A programmable controller housed in the liquid-cooled load bank controls the power draw and the heating of the mechanical load cell to control parameters through the mechanical load cell. The parameters replicate and simulate characteristics corresponding to a set of computing equipment that the electrical system and the mechanical system of the building will support after the commissioning of the building. The programmable controller has a user interface to cooperate with a digital display to display the parameters.

### NOTICE OF COPYRIGHT

A portion of this disclosure contains material that is subject to copyright protection. The copyright owner has no objection to the facsimile reproduction by anyone of the material subject to copyright protection as it appears in the United States Patent & Trademark Office's patent file or records, but otherwise reserves all copyright rights whatsoever.

### RELATED APPLICATION

This application claims priority to and the benefit of under 35 USC 119 of U.S. provisional patent application titled “Liquid Load Banks,” filed Aug. 13, 2024, Ser. No. 63/682,686, which is incorporated herein by reference in its entirety.

### FIELD

Embodiments of the design provided herein generally relate to test equipment. In an embodiment, the liquid-cooled load bank can validate a building's mechanical and electrical equipment.

### BACKGROUND

Critical equipment in a building needs to be tested and validated.

### SUMMARY

In an embodiment, a liquid-cooled load bank can contain an electrical load cell and a mechanical load cell to test and validate an electrical system with an electrical load and a mechanical system by heating a testing fluid in a circulation heater in the mechanical load cell and cooling of the mechanical load cell with the mechanical system in a building to validate the electrical system and the mechanical system of the building during a commissioning of the building. A programmable controller housed in the liquid-cooled load bank can control electrical power draw by the electrical load cell and can control the heating of the testing fluid through the mechanical load cell to allow control over parameters including a delta T temperature rise across the mechanical load cell, a delta P pressure drop across the mechanical load cell, and a flow rate through the mechanical load cell. The parameters of the delta T temperature rise, the delta P pressure drop, and the flow rate replicate and simulate characteristics corresponding to a set of computing equipment that the electrical system and the mechanical system of the building will be required to support after the commissioning of the building. The programmable controller has a user interface to cooperate with a digital display to display the parameters.

These and other features of the design provided herein can be better understood with reference to the drawings, description, and claims, all of which form the disclosure of this patent application.

### DRAWINGS

The drawings refer to one or more embodiments of the design provided herein, in which:

FIGS. 1A and 1B illustrate block diagrams of an embodiment of the liquid-cooled load bank that contains an electrical load cell and a mechanical load cell to test and validate an electrical system with an electrical load and a mechanical system by heating a testing fluid in a circulation heater in the mechanical load cell and cooling the mechanical load cell with the mechanical system in a building.

FIG. 2 illustrates a PID diagram of an embodiment of the mechanical load cell in the liquid-cooled load bank has the electric circulation heater with a pressure vessel, a pressure control valve, an inlet gate/ball valve, a return gate/ball valve, an input pressure sensor, an outlet pressure sensor, an input temperature sensor, a flow rate sensor, and an outlet temperature sensor.

FIG. 3 illustrates a block diagram of an embodiment of the electrical load cell in the liquid-cooled load bank has a series of resistive heating elements in an electrical parallel arrangement to allow the electrical power draw to be set and increased in fixed increments of a total electrical power draw that the electrical load cell is capable of in order to replicate and simulate characteristics corresponding to a set of computing equipment that the electrical system and the mechanical system of the building will be required to support after the commissioning of the building.

FIGS. 4A and 4B illustrate diagrams of an embodiment of the programmable controller housed in the liquid-cooled load bank configured to control electrical power draw by the electrical load cell and to control the heating of the testing fluid through the mechanical load cell to allow precise control over parameters to replicate and simulate characteristics corresponding to a set of computing equipment that the electrical system and the mechanical system of the building will be required to support after the commissioning of the building.

FIG. 5 illustrates a block diagram of an embodiment of the programmable controller cooperating with a digital display housed in the liquid-cooled load bank and a set of local manual switches on the front of the housing of the liquid-cooled load bank.

FIG. 6 illustrates a block diagram of an embodiment of the programmable controller has a user interface to cooperate with a digital display to display the parameters and icons to set up and/or launch routines to control the electrical load cell and the mechanical load cell to test and validate an electrical system with an electrical load and a mechanical system by heating a testing fluid in a building.

FIG. 7 illustrates a block diagram of an embodiment of the programmable controller having a user interface to cooperate with a digital display to display the parameters and a software routine to control individually the liquid-cooled load bank.

FIG. 8 illustrates a block diagram of an embodiment of the programmable controller having a user interface to cooperate with a digital display to display the parameters and a software routine to control a set of multiple networked liquid-cooled load banks cooperating in tandem with each other via a local digital screen on a first liquid-cooled load bank

FIGS. 9A and 9B illustrate block diagrams of an embodiment of the programmable controller that has a user interface to cooperate with a digital display in order to display a local digital icon for a software routine to control individually the liquid-cooled load bank and a network control icon for another software routine to control a set of multiple networked liquid-cooled load banks cooperating in tandem with each other via a local digital screen on a particular liquid-cooled load bank as well as via an external input from a computing device connecting up to the particular liquid-cooled load bank.

FIG. 10 illustrates a diagram of an embodiment of a computing device that can be a part of the systems associated with the liquid-cooled load bank and programmable controller discussed herein.

While the design is subject to various modifications, equivalents, and alternative forms, specific embodiments thereof have been shown by way of example in the drawings and will now be described in detail. It should be understood that the design is not limited to the particular embodiments disclosed, but—on the contrary—the intention is to cover all modifications, equivalents, and alternative forms using the specific embodiments.

### DESCRIPTION

In the following description, numerous specific details are set forth, such as examples of specific data signals, named components, number of servers in a system, etc., in order to provide a thorough understanding of the present design. It will be apparent, however, to one of ordinary skill in the art that the present design can be practiced without these specific details. In other instances, well-known components or methods have not been described in detail but rather in a block diagram in order to avoid unnecessarily obscuring the present design. Further, specific numeric references, such as a first server, can be made. However, the specific numeric reference should not be interpreted as a literal sequential order but rather interpreted that the first server is different than a second server. Thus, the specific details set forth are merely exemplary. Also, the features implemented in one embodiment may be implemented in another embodiment where logically possible. The specific details can be varied from and still be contemplated to be within the spirit and scope of the present design. The term coupled is defined as meaning connected either directly to the component or indirectly to the component through another component.

In general, a programmable controller (8) housed in the liquid-cooled load bank can control electrical power draw by an electrical load cell and can control the heating of the testing fluid through the mechanical load cell to allow control over parameters through the mechanical load cell and electrical load cell to replicate and simulate characteristics corresponding to a set of computing equipment that the electrical system and the mechanical system of the building will be required to support after the commissioning of the building.

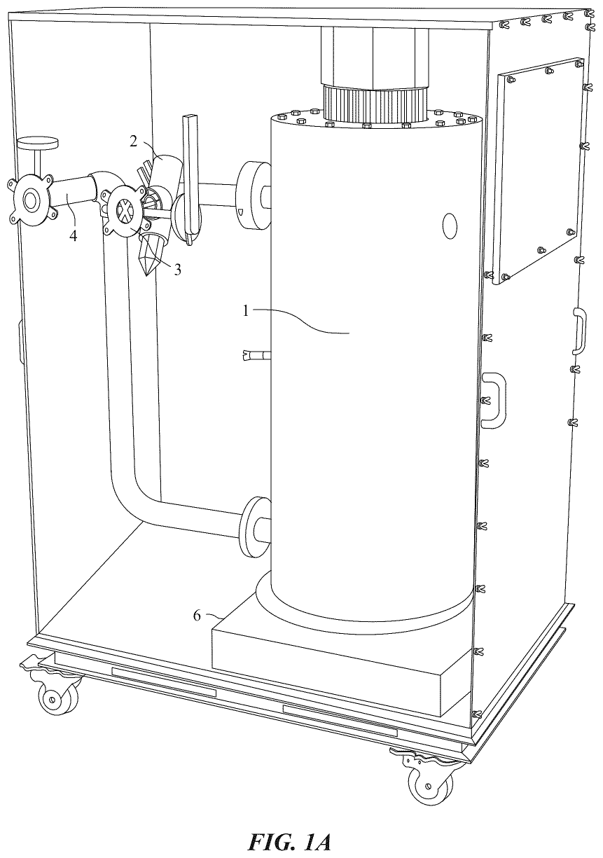

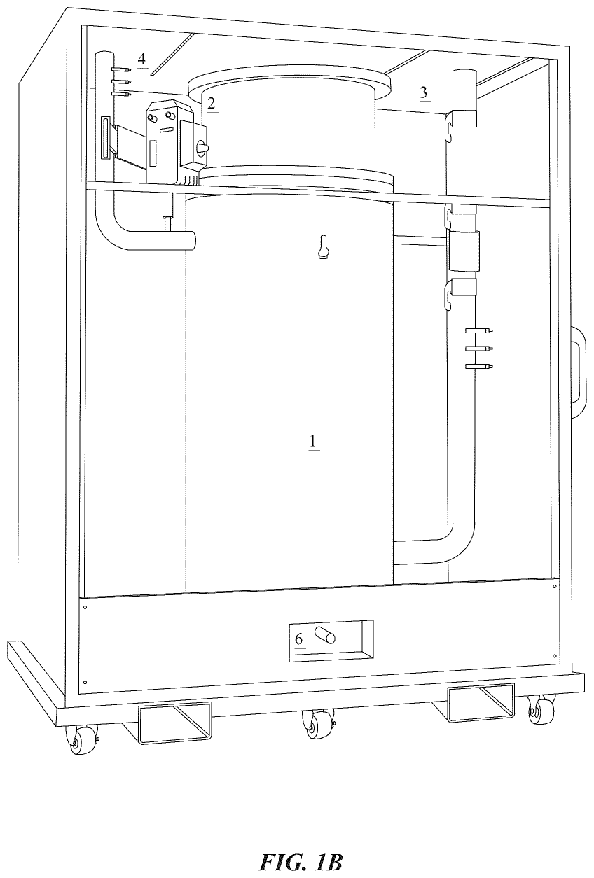

FIGS. 1A and 1B illustrate block diagrams of an embodiment of the liquid-cooled load bank that contains an electrical load cell and a mechanical load cell to test and validate an electrical system with an electrical load and a mechanical system by heating a testing fluid in a circulation heater in the mechanical load cell and cooling the mechanical load cell with the mechanical system in a building. The liquid-cooled load bank uses the electrical load cell and the mechanical load cell to validate the electrical system and the mechanical system of the building during the commissioning of the building.

The liquid-cooled load bank has a mechanical load cell for the mechanical system of the building. The mechanical load cell in the liquid-cooled load bank can have a circulation electric circulation heater (1) with a pressure vessel, a pressure control valve (2), an inlet gate/ball valve (3), a return gate/ball valve (4), an input pressure sensor, an outlet pressure sensor, an input temperature sensor, a flow rate sensor, and an outlet temperature sensor. Thus, the mechanical load cell in the liquid-cooled load bank can have an electric circulation heater (1), an inlet V-port stainless steel pressure control ball valve (2), an inlet valve (3), a return valve (4), stainless steel piping, a fill valve and a drain valve (6) to add and/or remove the testing fluid into the piping and pressure vessel of the liquid-cooled load bank, a pressure sensor, a flow sensor, a temperature sensor, a pressure relief valve and no Zinc in any component. The piping may be a 4-inch or 3-inch piping and mechanical connections on an exterior of the housing of the liquid-cooled load bank.

Referring to FIG. 1A, the electric circulation heater (1) with the pressure vessel can be located inside, along a side of the housing. The housing can have a side mount piping input and output connections. Referring to FIG. 1B, the electric circulation heater (1) with the pressure vessel can be located in the middle of the housing for weight distribution. The housing can have a top mount piping input and output connections.

Thus, the liquid-cooled load bank can have at least two types of configurations and housings—a first design that has the pipes and their connections coming straight out of the side of the housing, and a second design that has the pipes and their connections that come out of the top of the housing. The reason for the top mount is because sometimes the building's will have their chilled coolant system piping at the top of the facility, and sometimes building's will have their chilled coolant system piping, such as their technical water supply for critical loads, below the raised floor or on the side walls of the building, so the building may want different options, depending on what makes the most sense for that building.

The pressure vessel of the circulation heater (1) has heating elements inside of it. Those heating elements can be specially designed for the type of fluid, the Polypropylene Glycol (PG) 25%, 75% water. The heating elements are designed specifically to heat to exactly 500 kilowatts at 415V, or to draw 670 kilowatts at 480V, and they can be dual voltage. Thus, the heating elements can be a series of parallel heater elements that draw enough current to consume, for example, 500 kW at the applicable voltage of 415V. The liquid-cooled load bank can use the building's own cooling capability (e.g., building's cooling/chilled coolant system) to dissipate the heat from inside the pressure vessel.

The liquid-cooled load bank tests out and simulates heating by computing equipment, such as the heating from a chip inside a server, which has the characteristic of instantaneous heat rise and heat drop. Accordingly, the immersion heater elements' parallel arrangement is set up to mimic a way and a rate that a chip in a server heats up when in use, in order to simulate the currently most demanding computing equipment that a building may contain. The heater elements simulate the heat load and rate of heat load generated by a chip inside a server. The programmable controller (8) can activate all or just some of the electrical contactors for the heater elements and in different arrangements to match the simulated amount of power drawn and rate of instantaneous heat load generated by the computer equipment being simulated.

Note, the programmable controller (8) also works with the pressure control valve (2) in the mechanical load cell to simulate the type of pressure drop across a single server, a row of servers, etc., in a data center. A first type of individual server might drop 10 PSI across the server and have a specification requirement of an input pressure of 15 PSI. However, another type of server may have a specification requirement of an input pressure of 40 PSI and a drop of 25 PSI across a row of servers that have chips which are directly cooled by liquid cooling. The mechanical load cell in the liquid-cooled load bank has the ability to modulate and match the design criteria of all of the possible different computing equipment types that can be installed in a building, such as a data center, so that a user can test all of that together. The pressure control valve (2) is connected to the programmable controller. The V-port and an actuator on that pressure control valve (2) allow the programmable controller to input precision control of the pressure drop and flow rate within the mechanical load cell. The programmable controller may get the pressure indication from the input and output pressure sensors or merely dial to a certain percentage of open or closed. The programmable controller can control the V-port pressure control valve (2), the inlet gate/ball valve (3), and the return gate/ball valve (4) to control flow rate and pressure drop across the circulation heater (1) pressure vessel. The algorithm in the programmable controller (8) uses a feedback loop to get precise delta P pressure drops across the circulation heater (1), delta T temperature rises across the circulation heater (1), percent open or closed on the valve, the electrical load, specific flow rates, etc. from the different sensors in the mechanical and electrical load cells. The user interface of the programable controller allows a user to put in a wide variety of parameters the programable controller needs the mechanical load cell and/or the electrical load cell to simulate in order to replicate a particular server, rack of servers, row of racks of servers, and/or room of computing equipment including servers themselves, that would be installed inside of this data center, and the specifications that they say that they can handle. Each particular datacenter will have different computing equipment installed, as well as different service level agreements with its customers. Within a colocation data center, different service level agreements can exist between the enterprise customers and the datacenter within a single data center; and thus, commissioning of that building with multiple different sets of parameters needed to satisfy all of the different service level agreements.

In an embodiment, the pressure control valve (2) creates a restriction and the building's Cooling Distribution Units then increase or decrease pump power relative to their set points. So, the pressure control valve (2) creates a restriction on the flow of the technical fluid, for example, then the pump speeds up to create more flow, which in turn creates the pressure drop across the liquid cooled load bank; thus, simulating exactly how the servers will restrict flow rate and create a pressure differential.

The programmable controller (8) can control an operation of a pressure control valve (2) in the mechanical load cell and a set of resistive heating elements in a parallel electrical arrangement in the mechanical load cell to coordinate together in order to match a design criteria including the delta T temperature rise across the mechanical load cell, the delta P pressure drop across the mechanical load cell, and the flow rate through the mechanical load cell, to be capable of satisfying multiple different computing equipment types that can be installed in the building in order to replicate and simulate exact characteristics corresponding to the set of computing equipment that the electrical system and the mechanical system of the building will be required to support after the commissioning of the building.

The programmable controller (8) is housed in the liquid-cooled load bank and controls electrical power draw by the electrical load cell and controls the heating of the testing fluid through the mechanical load cell to allow precise control over parameters including a delta T temperature rise across the mechanical load cell, a delta P pressure drop across the mechanical load cell, and a flow rate through the mechanical load cell. The parameters of the delta T temperature rise, the delta P pressure drop, and the flow rate replicate and simulate characteristics corresponding to a set of computing equipment that the electrical system and the mechanical system of the building will be required to support after the commissioning of the building.

The liquid-cooled load bank supports pressure, temperature, and flow control. For example, the total flow can be 750 liters per minute, which must flow 1.5 LPM per kW @ 15 PSI. The mechanical load cell and its pressure regulation valve control the pressure between 5 PSI to 80 PSI. The filtering system in the mechanical load cell filters down to 25 microns but still supports at least 750 liters per minute flow rate. The liquid-cooled load bank has a 25-micron filter with a manual blowdown vent.

The testing fluid can be specifically a 25% Polypropylene Glycol-75% Water mixed fluid, or another similar liquid. Inlet temperature of the testing fluid can be 25-40 degrees C. at 80 PSI and up to 70 degrees C. at 80 PSI at the outlet.

The piping, pressure vessel, and filter of the liquid-cooled load bank use stainless steel or other similar material that is compatible with these liquid cooling systems in a data center.

The liquid-cooled load bank provides a heat dissipation testing solution to test the liquid cooling system in a data center. The liquid-cooled load bank provides mechanical testing of datacenter liquid cooling systems with heating of the testing fluid. The liquid-cooled load bank provides a fully integrated testing and commissioning solution for both electrical and mechanical systems in mission-critical facilities, such as a datacenter. The liquid-cooled load bank delivers a testing and validation tool for mission-critical commissioning, ensuring mechanical cooling systems, such as Technology Cooling Systems (TCS), Technology Water Distribution Systems (TWDS), etc., and other critical electrical infrastructure, such as those protected by uninterruptible power supplies (UPS) to meet the highest reliability standards. The liquid-cooled load bank provides reliable, repeatable, and verifiable testing of the building's facilities, such as a datacenter, the electrical system as well as provides liquid cooling. The liquid-cooled load bank provides electrical testing of datacenter electrical system with an electrical load.

Referring back to FIGS. 1A and 1B, the liquid-cooled load bank is engineered with multiple automatic protections, such as a mechanical minimum flow safety switch, a mechanical over temperature switch, a mechanical over pressure safety valve 150 PSI, to automatically shut down mechanisms regarding minimum flow per kW, maximum temperature, and maximum pressure in the system. These safeguards ensure the safe operation of the liquid-cooled load bank and the existing building's infrastructure and equipment, such as computing equipment under test, to prevent potential failures during the commissioning process of the building and/or later when the building goes live. For example, the liquid-cooled load bank may also be used in a permanent installation for supplemental heat load for the building. The idea here is the IT computing equipment can ramp up and down so fast that the cooling equipment installed in the building cannot efficiently sustain those changes. But, the installed liquid-cooled load bank can rapidly change its heat load within 16 milliseconds or less. So, the installed liquid-cooled load bank could be used to provide sense operating temperature in the cooling system and provide supplemental heat load during data center operation, not just for commissioning. The heat load profile will have more smooth heat rises and falls, and less extreme spikes making the operation of the building's cooling system more optimized and less rough on its pumps, chillers, etc.

Next, the designed minimum flow rate for ensuring equipment does not get damaged is 0.75 liters per minute per kilowatt with a design nominal flow rate of 1.5 liters per minute per kilowatt and a maximum flow rate set at 3.0 liters per minute per kilowatt and a maximum pressure of 150 PSI.

The emergency pressure relief valve set at 150 psi to blow off pressure over satisfies an ASME requirement. The electric circulation heater (1)/pressure vessel has an ASME certification stamp on it. The pressure vessel is made of 316 stainless steel to get an ASME stamp, with certified ASME welding, the flange type selected, and how the heating elements are bolted into the top and bottom of the pressure vessel of the circulation heater (1). In an embodiment, just the surfaces, such as piping and valves (e.g., wetted materials), in contact with the technical fluid are made of 316 stainless steel and other portions of the pressure vessel are made of regular steel.

Data center performance depends on the flawless integration of electrical and mechanical systems. The liquid-cooled load bank provides a comprehensive testing solution designed to fully commission both the electrical and cooling infrastructure of a building with a high density of computing equipment. The software routines in the programmable controller (8), the mechanical load cell, and the electrical load cell of the liquid-cooled load bank are specifically configured to facilitate the commissioning of the mechanical system independent of the electrical system in the building but also to facilitate validation of both the mechanical system and the electrical system simultaneously at a same time with each other. The software routines in the programmable controller (8) can also commission the electrical system independently of the mechanical system. The liquid-cooled load bank provides a testing and validation tool to simulate real-world electrical and mechanical load conditions and can validate those electrical and mechanical conditions during commissioning of the building and/or optionally during periodic tests when the building is already commissioned. The liquid-cooled load bank ensures infrastructure meets operational and reliability Service Level Agreements (SLAs) before going live. The liquid-cooled load bank validates both electrical and cooling infrastructure in a datacenter. The liquid-cooled load bank is designed to rigorously validate both electrical system and mechanical system simultaneously/at the same time. The liquid-cooled load bank supports Level 4 & Level 5 commissioning in a datacenter.

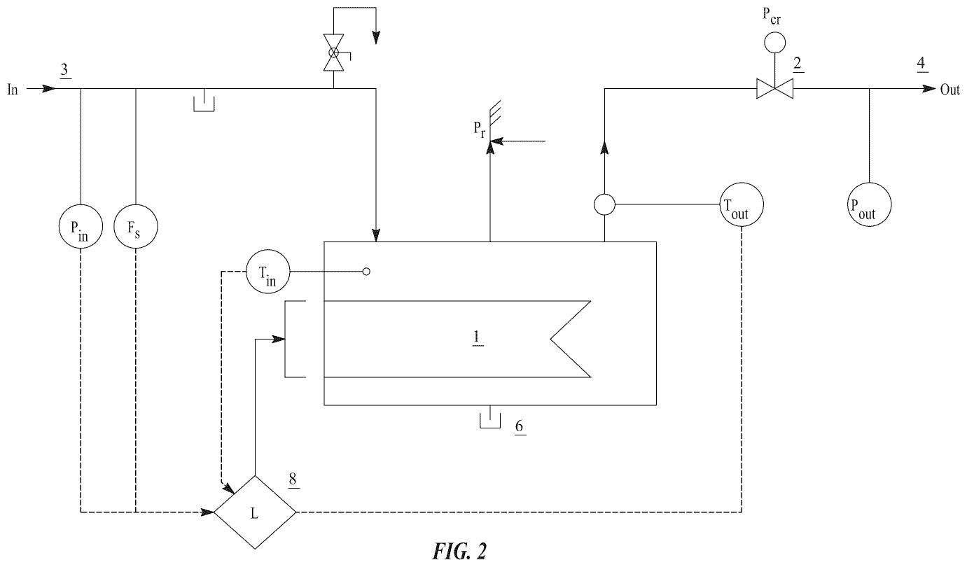

FIG. 2 illustrates a PID diagram of an embodiment of the mechanical load cell in the liquid-cooled load bank has the electric circulation heater with a pressure vessel, a pressure control valve, an inlet gate/ball valve, a return gate/ball valve, an input pressure sensor, an outlet pressure sensor, an input temperature sensor, a flow rate sensor, and an outlet temperature sensor. In an embodiment, merely an inlet ball/gate valve and a pressure control valve (2) are implemented and the outlet ball/gate valve is not implemented.

The liquid-cooled load bank has advanced instrumentation & monitoring in the mechanical load cell for fluid temperature inlet and outlet, fluid pressure, and fluid flow rate. The programmable controller (8) (L) is configured to receive input from an input pressure sensor, a flow sensor, an input temperature sensor, an output pressure sensor, and an output temperature sensor, then to send inputs into a pressure control valve (2) and heating elements in the circulation heater (1) according to a software routine in the programmable controller (8) to control how open the pressure control valve (2) will be and a power draw by the heating elements in light of a feedback loop from each of the sensors in order to satisfy one or more parameter set points inputted by an operator/user. Note, the additional connections to the pressure control valve (2), the inlet valve (3), the return valve (4), etc., are not shown but can exist from the programmable controller (8). The programmable controller (8) (L) receives input from the input pressure sensor, a flow sensor, the input temperature sensor, the output pressure sensor, and an output temperature sensor, then sends inputs into the pressure control valve (2) and the heating elements in the circulation heater (1) according to routines and algorithms in the programmable controller (8) to modulate all these things work in conjunction with each of with a feedback loop for each of the sensors to satisfy the parameter set points inputted by the operator/user.

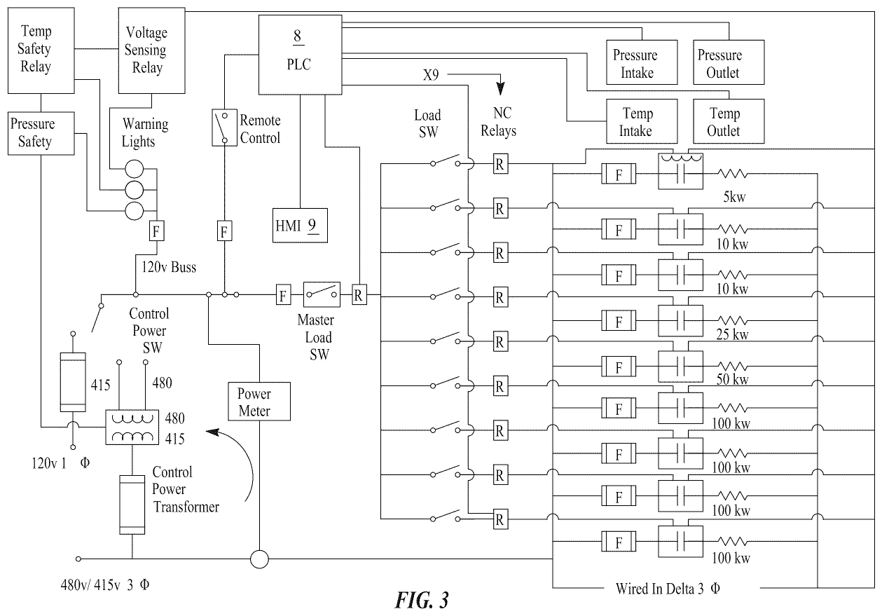

FIG. 3 illustrates a block diagram of an embodiment of the electrical load cell in the liquid-cooled load bank has a series of resistive heating elements in an electrical parallel arrangement to allow the electrical power draw to be set and increased in fixed increments of a total electrical power draw that the electrical load cell is capable of in order to replicate and simulate characteristics corresponding to a set of computing equipment that the electrical system and the mechanical system of the building will be required to support after the commissioning of the building.

The test equipment in the liquid-cooled load bank has an electrical load cell for testing the electrical system of the facility.

The test equipment in the liquid-cooled load bank can include an example electrical load cell that consists of a series of resistive heating elements, such as a 5 kW resistive heating element, two 10 kW resistive heating elements, a 25 kW resistive heating element, a 50 kW resistive heating element, and four 100 kW resistive heating elements, all wired in delta phase three phase. Each of the resistive heating elements has a relay (R) that can be triggered by input from the programmable controller (8) (PLC) as well as by a set of local manual switches (local SW) on the front of the housing of the liquid-cooled load bank. Additionally, the diagram shows a fuse (F), but also a circuit breaker, for safety protection, which could be in the circuit pathway to each one of the resistive heating elements.

Inputs come into the programmable controller (8), designated as PLC, from the input pressure sensor, the outlet pressure sensor, the input temperature sensor, the flow rate sensor, as well as the outlet temperature sensor. The test equipment in the liquid-cooled load bank can include the input pressure sensor, the outlet pressure sensor, the input temperature sensor, the flow rate sensor, the outlet temperature sensor, a power meter, a voltage meter, and an electrical current meter. The test equipment in the electrical load cell includes one or more electrical meters that can provide an indication of total power, voltage, and electrical current. The power meter shows its input going into the program controller on the lower left-hand side. The control power transformer either takes power and connects up to 480 volts from the building's electrical supply or 415 volts from the building's electrical supply, depending upon the building type. A center tap comes off of the control power transformer to allow a 120 Volt single-phase power to be supplied to operate the programmable logic controller and some of the local lights and other functions in the liquid-cooled load bank. The programmable controller (8) will also take input from the remote-control switch or local digital control depending upon whether the user has selected local digital or network controlled. The HDMI input comes in from the touch screen on the digital display (9). The master load switch (master load sw) allows for block loading of the preselected load steps by turning the master load switch off, selecting the desired loads, then turning the master load switch on, thus applying the selected loads simultaneously. The remote switch allows selection between remote and local operation. Also, the electrical load cell includes an individual voltage sensing relay for safety that is separate from the programmable logic controller to make sure that overvoltage and undervoltage conditions trigger the safety feature along with any possible coding inside the programmable logic controller. Also, the electrical load cell includes a temperature safety relay that when the temperature reaches above a maximum set point at the temperature outlet to trigger this safety. Another safety for this system is the pressure safety cut off which receives an input from the pressure outlet and triggers a cutoff when the pressure reaches too high inside the system. Each of the safety relays of sensing dangerous conditions has an associated warning light that will show up on the front housing of the liquid-cooled load bank. Note, each resistive heating element shown can actually be a group of three resistors, one resistor on each leg of the 3-phase AC, for each resistor, shown in the electrical diagram. Each “step” such as the 5 kW step, can be actually comprised of three separate 1.66 kW resistive heating element that when wired together in a delta configuration, make a 5 kW total step. This is true of each of the steps. The resistive heating elements can have multiple 3 or more elements combined within them to get to the right total kW.

As discussed, the programmable controller (8) has a software routine to control the testing of the building's electrical system in a step fashion by applying specific electrical loads (e.g. 5, 10, 15, . . . , 490, 495, 500 kW at 415V) with all the parameters shown on the digital display (9) and recorded for verification records/auditing. The liquid-cooled load bank has the physical components in the electrical load cell and in the mechanical load cell as well as the programming in the programmed controller to step the kW load being tested and validated. A single liquid-cooled load bank can provide the 500 kW total load at 415V (or 669 kW at 480 V) as well as power increases in fixed steps up to that 500 kW total load (or 669 kW at 480 V). An example set of fixed increases in kW mechanical heat and/or electrical draw load can be 5, 10, 10, 25, 50, 100, 100, 100, and 100, which can be added together in any sequence to make an example load anywhere 5 and 500 in 5 kW steps. For example, 5+10+50+100+100 makes a total of 265 kW and 10+10+50+100+100 would make a total of 270 kW. The number of heating elements, the type of heating elements, and the parallel series arrangement of these resistive heating elements can be configured to get to these very specific load steps so that the liquid-cooled load bank can step all the way through from 0 to 500 kilowatts at 415 volts AC. A similar stepping process exists at 480 volts AC for this liquid-cooled load bank from 0 to 669 kW at 480 volts AC. The stepping process can assist and be used during the commissioning process.

Note, when the programmable logic controller has merely the 5 kW resistance heating element and the 10 kW resistance heating element heating up the technical fluid, then the technical fluid will slowly heat up. However, when the programmable logic controller engages the 5 kW resistive element contactor, and, for example, two 100 kW contactors (205 kW), then the water will heat up at a significantly faster rate than when only 15 kW total of resistive heating elements was engaged. The programmable controller (8) can also insert slight delays in time between activating the relay and contactor for each of the heating elements in the set being activated in order to control the rate of heat increase of water passing through the circulation heater (1) at the measured flow rate through the circulation heater (1). The programmable controller (8) can replicate temperature changes so as to change the temperature of the fluid specifically needed to simulate the set of computing equipment being validated during the commissioning. The programmable controller (8) can to select different arrangements of resistive heating elements in the circulation heater (1) of the mechanical load cell and reference a heating up table and an amount of energy added to a volume of water flowing through a pressure vessel of the circulation heater (1) in the mechanical load cell to accurately calculate and create a specific rate of heat increase and/or heat decrease for the testing fluid flowing through the circulation heater (1). The amount and type of resistive heating elements being engaged allows the controller based on flow rate to go from a very low heat load up to 500 kilowatts of heat load very fast, which also replicates and simulates how fast a chip in a server these days can go from being cooled to instantly very hot and generating a lot of heat.

The liquid-cooled load bank has varying sizes available when two or more liquid-cooled load banks are used as a set. The initial design is 500 kW. A single liquid-cooled load bank unit can supply smaller heat loads, such as 250 kW, and a set of two 500 kW liquid-cooled load banks in parallel can supply a heat load of 1,000 kW or larger. Operators are able to set a specific kW through the programmable controller (8) and then see that kW loaded electrically. Again, the liquid-cooled load bank has a set of controls to be able to step at minimum 5 kW increments evenly loaded across three phases at 415V and 6.7 kW increments evenly loaded across three phases at 480V.

The programmable controller (8) can also have a software routine to control a software-coded minimum flow safety set point, a software-coded over pressure safety set point, and/or a software-coded over temperature protection set point.

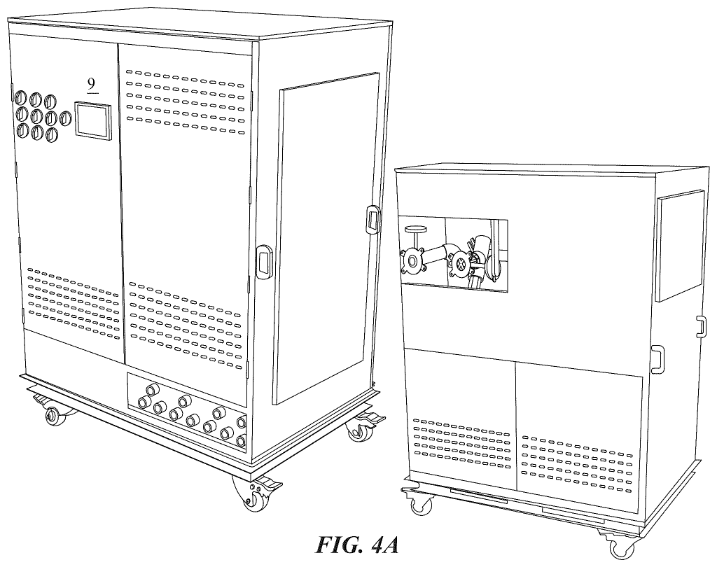

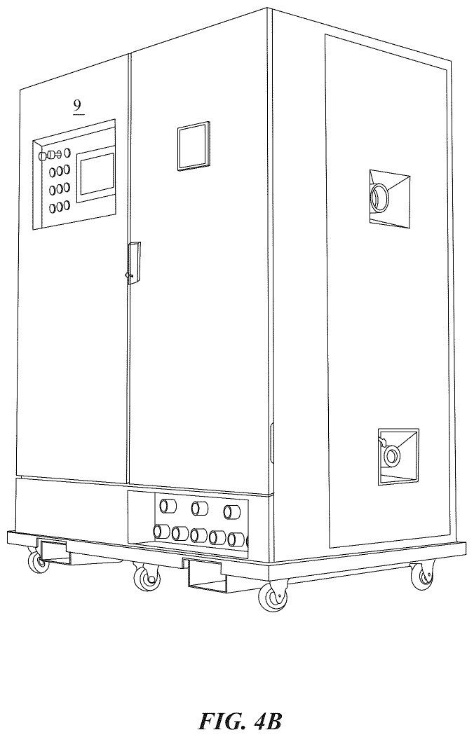

FIGS. 4A and 4B illustrate diagrams of an embodiment of the programmable controller housed in the liquid-cooled load bank configured to control electrical power draw by the electrical load cell and to control the heating of the testing fluid through the mechanical load cell to allow precise control over parameters to replicate and simulate characteristics corresponding to a set of computing equipment that the electrical system and the mechanical system of the building will be required to support after the commissioning of the building.

An example 500 kW liquid-cooled load bank contains electrical and mechanical test equipment in electrical and mechanical load cells for a data center. The liquid-cooled load bank can provide, for example, 500 kW electric load to the building's electrical supply systems while simultaneously providing 500 kW mechanical heat load to the building's mechanical “technology cooling system.” The technology cooling system in the datacenter couples up to the liquid-cooled load bank, which can be used to cool integrated chips housed and powering servers themselves. The liquid-cooled load bank can provide, for example, 500 kW electric load of electrical load at 415 V and, for example, 500 kW mechanical load (e.g., liquid heating) capacity.

The liquid-cooled load bank can provide 500 kW at 415 three phase volts AC and 670 kW liquid-cooled load bank at 480 three phase volts AC engineered to validate the reliability of mission-critical data centers and high-density compute environments. The resistive heating elements in the circulation heater (1) are dual voltage 500 kilowatts at 415V and 670 kilowatts at 480V.

The liquid-cooled load bank is electrically configured to support dual voltage capability between 415 three phase volts AC and 480 three phase volts AC. The bottom right of the housing of the liquid-cooled load bank has on its external surface camlock electrical connections capable of supporting a power input between 415V and 480V three phase power at 400 amps with a maximum voltage rating of up to 600 volts. The housing of the liquid-cooled load bank is constructed to have electrical connections on its external surface to support a power input between 415V AC and 480V AC three phase across resistive heating elements in the circulation heater (1) of the mechanical load cell and the electrical load cell as well as a control power transformer to tap to supply a 120 VAC control power to use on electrical equipment in the liquid-cooled load bank. The 400-amp camlock electrical panel mount male connectors are used to quickly and temporarily connect to each of the three phases of AC and the electrical ground connections. The camlock electrical male connectors plug in and twist with quick-connect cables to connect electrical power to the liquid-cooled load bank. The liquid-cooled load bank, through the camlock electrical male connectors, electrically connects to, for example, electrical panels, such as power distribution units, and/or electrical busways, inside the data center. Note, the electrical connector panel on the liquid-cooled load bank can also be connected with pigtails, with bare ended copper wire, and using mechanical lugs to connect it to a PDU or a RPP panel. When the liquid-cooled load bank connects to the example busway, then the electrical load cell inside the liquid-cooled load bank simulates being the critical electrical load power from the busway. The electrical load cell with a circulation heater (1) inside the liquid-cooled load bank simulates and actually creates that electrical current draw and then dissipates the heat from the current draw.

The liquid-cooled load bank has a controls and power enclosure. The liquid-cooled load bank has advanced instrumentation and monitoring for total electrical power draw, voltage on each phase/leg of the three phases, and amperage on each phase/leg of the three phases, and the average of the three phases.

The liquid-cooled load bank can have a battery to provide electrical power when not connected to AC power. The battery backup can be sized in amp hours capacity to support at least, for example, 10 minutes of testing at full 500 kW power draw when no external AC power from the building is being supplied to the liquid-cooled load bank. The liquid-cooled load bank can have a power transformer to input 120 VAC control power with a dual tap power transformer (480V and 415V) to supply the 120V. The liquid-cooled load bank can have a power transformer to input 24 V DC control power with a dual tap power transformer (480V and 415V) to supply the 24 V DC. The battery backup can be connected to step up DC to AC rectifier-transformer in order to supply the 120 VAC control power. The battery backup can be connected to a 24 V DC control power bus way to supply the 24 V DC control power.

The programmable controller (8) has a user interface to cooperate with a digital display (9) to display the parameters and a non-volatile memory to store the parameters for validation records/auditing. Note, any software instructions in the programmable controller (8) are stored in one or more non-transitory storage mediums in an executable format to be executed by one or more processors.

The liquid-cooled load bank has a portable construction. The liquid-cooled load bank is a portable device that can be moved to locations within a datacenter to connect up to the electrical and/or mechanical portions of that datacenter being tested. The liquid-cooled load bank has a full-frame enclosure with a separate metal cage that the entire unit rolls into. The liquid-cooled load bank has dimensions for ease of shipping in a dry van LTL and/or shipping container. The liquid-cooled load bank has forklift pockets and casters for wheels so that this very heavy liquid-cooled load bank can be easily shipped to and/or wheeled to a location in the building where the testing will occur. Note, the casters for wheels are mechanically connected so that they may be removed during the shipping process to make it easier to ship the liquid-cooled load bank. For example, the forklift pockets are bolted to a bottom metal layer of the enclosure, and then the casters are mounted into that bottom metal layer, which can be unbolted for shipping. The casters may also be mounted with a quick release pin, allowing for easy removal for shipping.

The liquid-cooled load bank has a user interface touch screen and a set of manual switches in the upper left, the electrical connections to the building's electrical connections on the lower middle, and the piping connections to the building's mechanical connections on the right-hand side. The mechanical connections on the surface of the liquid-cooled load bank may be 4″ mechanical pipe connections, which come with a 3″ piping reducer adapter, 3″ piping connections, or another dimension. Some buildings' cooling supply can use 4″ connections and some can use 3″ connections. Note, liquid-cooled load bank may use, for example, 3″ piping connections with a 5″ adapter to increase an outlet piping size that needs a larger piping connection. For instance in a scenario of when the liquid-cooled load bank is used to test buildings that employ 2 phase cooling systems that use cooling fluid utilized in both a liquid phase and then in a gaseous phase in order to cool their associated heat loads, then the liquid-cooled load bank can use its 3″ piping connections to connect to the building's 3″ piping connection and its 3″ to 5″ adapter to connect to the building's 5″ piping connection.

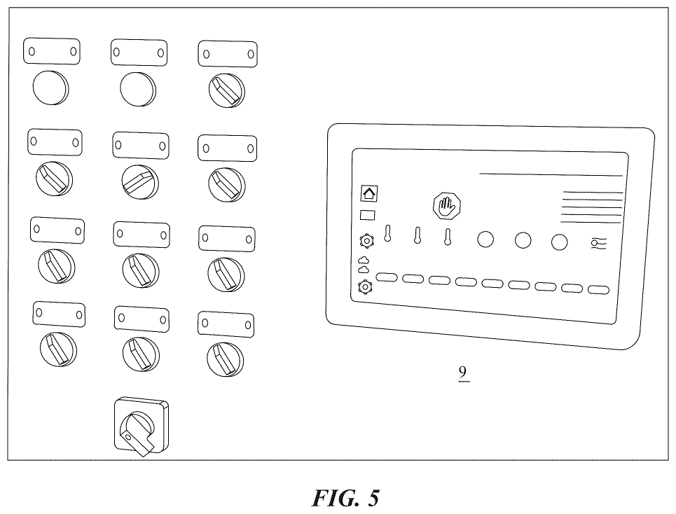

FIG. 5 illustrates a block diagram of an embodiment of the programmable controller cooperating with a digital display housed in the liquid-cooled load bank and a set of local manual switches (local SW) on the front of the housing of the liquid-cooled load bank.

The programmable controller (8), such as a programmable logic controller (PLC), is coded with algorithms, routines, and other logic to automatic flow control to any number of parameters, such as a target pressure drop or flow rate.

The user interface of the digital display (9) can be implemented as a touch screen. Note, a set of manual switches can be on this housing to throw. A first switch can switch the liquid-cooled load bank from automatic control by a programmable controller (8) over to manual control. In manual control, the set of manual switches can activate the load steps at, for example, increments of 5, 10, 10, 25, 50, 100, 100, 100, and 100 kW at 415V. Thus, the main unit in manual mode has simple toggle switches for each load step and a master load switch for applying preset loads from the simple toggle switches.

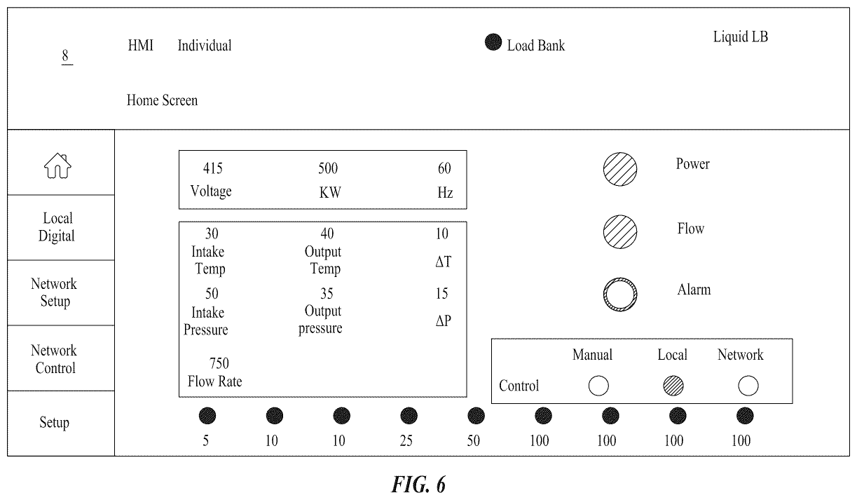

FIG. 6 illustrates a block diagram of an embodiment of the programmable controller has a user interface to cooperate with a digital display to display the parameters and icons to set up and/or launch routines to control the electrical load cell and the mechanical load cell to test and validate an electrical system with an electrical load and a mechanical system by heating a testing fluid in a building.

The far-left hand is a column of control icons of the digital display (9) is a control scheme of how the operator wants to control an operation of the liquid-cooled load bank, such as step kW increases. The column of control icons shows a local digital icon, a network setup icon, a network control icon, and a home screen icon. The operator/user can select to control the step kW increases either via the local digital screen or via a network setup and network control. The digital display (9) cooperating with the programmable controller (8) has a first section to display parameters associated with the electrical load cell being tracked and/or monitored, such as 415 voltage, 500 kW, 60 Hertz, etc. The digital display (9) cooperating with the programmable controller (8) has a second section to display parameters associated with the mechanical load cell being tracked and/or monitored such as, for example, an input temperature of 30° C., an output temperature of 40° C., a delta T temperature rise of 10° C., an input pressure of 50 PSI, an output pressure of 35 PSI, a delta P pressure drop of 15 PSI, and a flow rate of 750 liters per minute.

The liquid-cooled load bank has the ability to operate in three different modes. The first mode allows the user to operate the liquid-cooled load bank in the local mode by clicking the local digital button and then the programmable controller (8) operates all of the functions. The programmable controller (8) turns the load steps on and off.

However, the second mode that the user can operate the liquid-cooled load bank is the manual mode by turning a manual switch on the front panel of the unit from automatic over into manual mode. The operator can then use the manual load increase switches. A light lights up to indicate the liquid-cooled load bank is in manual mode on the front panel. All of the control functionality of the touch screen goes away, and everything goes by operation of the manual switches. This allows for the tester/operator to manually perform any commissioning operation, even when the programmed controller may not have been coded to perform a specific operation. An operator can manually flip switches and turn the liquid-cooled load bank and its resistive heating elements on.

The third mode is that the user can operate the liquid-cooled load bank in the networked mode. The network control icon/routine controls multiple liquid-cooled load bank units, either with the programmed controller of one of the liquid-cooled load banks or with the laptop.

On the home screen, displayed at the top is an actual reading coming from the power quality meter of total Power being drawn, Voltage being measured coming from the power quality meter or another sensor, and the Frequency coming from the power quality meter or another sensor. The example shows current conditions of an average voltage across all three legs/phases is 415 v, currently drawing 500 kW, at 60 Hertz. The electrical parameters that are monitored and displayed include features such as electrical power kilowatts (kW), amps, frequency, and voltage.

The digital display (9) can also display indicator lights (e.g., green light) for power being on, flow rate being in the requested flow rate, and an alarm (e.g., red light) for an alarm condition.

The second section of the digital display (9) displays example mechanical load cell parameters being monitored, such as the intake temperature is 30° C., the output temperature is 40° C., and the circulation heater (1) is operating at a 10 degree delta change in temperature. Similarly, the digital display (9) displays example parameters of input air pressure of 50 PSI, pressure output of 35 PSI, and a delta P of 15 PSI of change in pressure. The digital display (9) displays example parameters of a current flow rate of 750 liters per minute. Across the bottom, the first section of the digital display (9) displays how many of the load steps are engaged (e.g., 5, 10, 10, 25, 50, 100, 100, 100, and 100 at 415V). If the liquid-cooled load bank connects to a 480-volt input, then those fixed steps would be larger numbers.

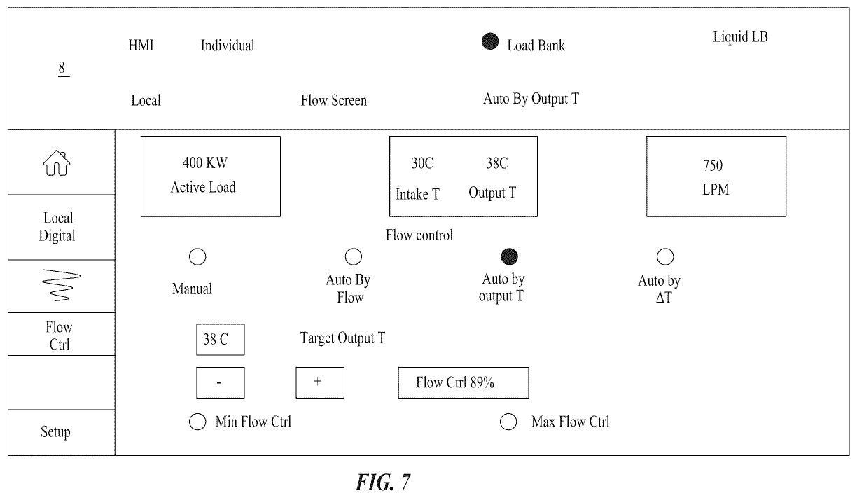

FIG. 7 illustrates a block diagram of an embodiment of the programmable controller having a user interface to cooperate with a digital display to display the parameters and a software routine to control individually the liquid-cooled load bank.

The programmable controller (8) has various software routines to control the load cells by parameters such as i) by kW, ii) by Delta T, iii) by max temperature, all with the parameters shown on the digital display (9), and recorded for verification records/auditing. Through the touch screen, the operator can input various parameters to control the validation process such as a desired flow rate, output pressure of fluid system, the pressure drop across the circulation heater (1), change in the Delta T temperature across the circulation heater (1), and the rate of increase and/or decrease of temperature change across the circulation heater (1), percentage openness of the pressure control valve (2), amount of heat load and/or electrical power draw being simulated, and various combinations of these parameters, which then can be monitored by the sensors and programmable controller (8) in the liquid-cooled load bank and then displayed by one or more screens on the touch screen controller. For example, the display screen is showing an output controlled by the output temperature of 38° C. and controlled by the flow valve being at 89%. The programmable controller cooperating with the rest of the components in the liquid-cooled load bank controls an output temperature at 38° C. with an input temperature of 30° C., has an active load being drawn by the resistive heater elements of 400 kilowatts, and then a flow rate of 750 liters per minute. Also, the light indicates that currently the flow control is based on output temperature rather than being controlled by a delta T temperature, or being controlled by a certain percentage of flow rate, or being in manual control. In addition, when the programmable controller (8) is controlling the pressure control valve (2) by percentage open, then the digital display (9) shows that a user may increase or decrease the percent open of the pressure control valve (2) by ±1% by tapping on the plus or minus icons. Note, a light will activate when the liquid-cooled load bank is at a minimum flow allowed as well as a maximum flow rate allowed. For example, the programmable controller (8) will not allow the pressure control valve (2) to close farther than 35% as a safety, or allow lower than 10 liters per minute as a minimum as a safety, or a maximum outlet temperature of 70 degrees C. as a maximum, or a pressure of 80 PSI at a maximum. The programmable controller (8) will modulate through an algorithm to control the mechanical components and electrical components in the liquid-cooled load bank to hit/satisfy the programmed in parameter set points and then display the corresponding set points and system parameters. Again, the programmable controller (8) cooperates with the components in the mechanical and electrical load cells in the liquid-cooled load bank to modulate the mechanical and electrical components to achieve the current combination of one or more parameters set as the target set point(s).

The programmable controller (8) has electrical connections and control over the pressure control valve (2), the inlet gate/ball valve (3), the outlet gate/ball valve, and the arrangement of heating elements in the circulation heater (1) in the liquid-cooled load bank to allow precise control over multiple parameters including i) delta T temperature degree change between the intake temperature and output temperature from the circulation heater (1) as well as delta P pressure drop across the circulation heater (1) between the input pressure and the output pressure from the circulation heater (1) and the flow rate of fluid through the circulation heater (1) to better (more accurately and precisely) a best true simulation of replicating to match the exact characteristics of (delta T temperature degree, delta P pressure drop, and flow rate) computing equipment (e.g. different type of servers) that will be installed in that particular building with that building's chilled water system in place to provide for a better validation during a commission process of a building across a wide range of possible computing equipment that could be installed in a given building. A first building can have a first set of computing equipment and chilled water cooling system that has a first set of characteristics of delta T temperature degree, delta P pressure drop, and flow rate through that first set of computing equipment to satisfy validation requirements, including any SLAs, during a commission process of the first building; and, a second building can have a second set of computing equipment and chilled water cooling system that has a second set of characteristics of delta T temperature degree, delta P pressure drop, and flow rate through that second set of computing equipment to satisfy validation requirements during a commission process of the second building with the same liquid cooling load bank. However, the set of computing equipment with its characteristics of a required delta T temperature degree, operating pressure of fluid in the system, a rate of increase or decrease of temperature over time, a delta P pressure drop, and flow rate through that set of computing equipment can also be more granular to multiple sets of computing equipment within a single building. Each set of computing equipment with its own characteristics of a required delta T temperature degree, operating pressure of fluid in the system, a rate of increase or decrease of temperature over time, a delta P pressure drop, and flow rate through that set of computing equipment being validated according to its own commissioning requirements with the same liquid cooling load bank. Generally, the operation of the V-port of the pressure control valve (2) can set the delta P pressure drop and flow rate by itself, but the inlet gate/ball valve (3) and the outlet gate/ball valve can also be throttled in an amount of openness to assist in a rough setting of these parameters. In an embodiment, when the liquid cooled load bank implements 3″ piping, then the corresponding 3″ control valve (2) can set the delta P pressure drop and flow rate more accurately and in finer increments by itself than, for example, with a 4″ pressure control valve (2) by the same manufacturer. The smaller diameter of the pressure control valve (2) allows a greater level of incremental control over the delta P pressure drop and flow rate for a same 1% increase in openness of the pressure control valve when the pressure control valve (2) is 3″ vs 4″. Generally, the operation of the V-port of the pressure control valve (2) in coordination with the series and arrangement of heating elements in the circulation heater (1) in the liquid-cooled load bank allow precise control over the delta T temperature degree rise and rate of increase or decrease of the temperature change in light of the delta P pressure drop and flow rate through that circulation heater (1) which is replicating and simulating the set of computing equipment being validated.

The programmable controller (8) has various software routines to control a type of test parameters, such as i) by kW, ii) by Delta T, iii) by max temperature, all with the parameters shown on the digital display (9), and recorded for verification records/auditing. The programmable controller (8) has a software routine to control flow monitoring with the digital display (9) where all of the parameters are shown on the digital display (9) and recorded for verification records/auditing. The programmable controller (8) has a software routine to control pressure by monitoring a pressure drop shown on the digital display (9) and recorded for verification records/auditing. Thus, the programmable controller (8), such as a PLC, is coded to control automatic flow rate control to target pressure drop or flow rate with the parameters shown on the digital display (9) and recorded for verification records/auditing.

In addition, the programmable controller (8) has a software routine to control electrical power, voltage, and amperage current digital display (9) with all the parameters shown on the digital display (9) and recorded for verification records/auditing.

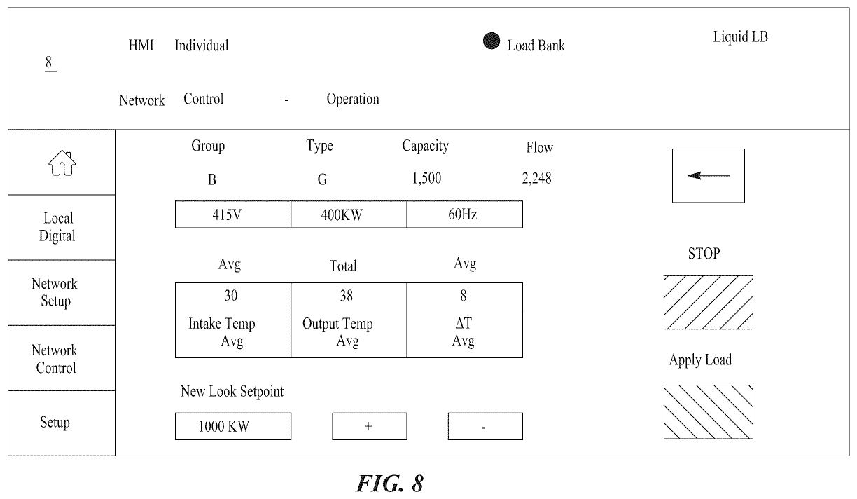

FIG. 8 illustrates a block diagram of an embodiment of the programmable controller having a user interface to cooperate with a digital display to display the parameters and a software routine to control a set of multiple networked liquid-cooled load banks cooperating in tandem with each other via a local digital screen on a first liquid-cooled load bank

The programmable controller (8) and the mechanical and electrical components within the liquid-cooled load bank replicate and simulate the flow rate, the operating pressure of fluid system, the pressure drop, the change in the Delta T temperature, and the rate of increase and/or decrease of temperature change of a set of computing equipment needed to be simulated by matching the characteristics of that set of computing equipment being validated. The same liquid-cooled load bank does this for a wide variety of sets of computing equipment to be simulated, where each set of computing equipment can have a different set of requirements. The programmable controller (8) and the mechanical and electrical components within the liquid-cooled load bank can replicate and simulate the set of computing equipment—an individual server, a rack of servers, a row servers, and/or the whole white space room of computing equipment—because the validation requirement may not be just about the individual servers themselves. The building's pumps, CDUs, the building's valves and piping all need to be part of the validation and commissioning process as well. Note, the mechanical heat load validation can occur separately from the electrical power draw validation in the commissioning process, but the same liquid-cooled load bank can simultaneously simulate the electrical power draw load and the mechanical heat load requirements during the same commissioning process. The same liquid-cooled load bank can perform testing and produce validation report test results for the mechanical heat load validation process, or for the electrical power draw validation separately from the mechanical heat load validation process, or for the mechanical heat load validation process and the electrical power draw validation simultaneously. Note, the same liquid-cooled load bank can be an individual 500 kW liquid-cooled load bank or a group of individual 500 kW liquid-cooled load banks. A white room in a datacenter that has 3,200 kilowatts of computing equipment would use seven individual 500 kW liquid-cooled load banks, each cooperating with each other to supply roughly 460 kW of heat load and/or electrical power draw for a total of 3,200 kilowatts of simulated and replicated computing equipment.

Next, a white room in a datacenter that has 3,200 kilowatts computing equipment may have one of the validation processes to test the heat load and/or electrical power draw at certain percentages of total load such as, for example, at five different fixed levels of 10%, 25%, 50%, 75%, and 100% of that 3,200 kilowatts load for the computing equipment that is or will be installed in the building. In an embodiment, the validation processes to test the heat load and/or electrical power draw at certain percentages of total load such as at each 5% all the way up to 100% of the total percentage of the room.

The user interface screen for network control has icons and parameter displays to show how a networked group of liquid-cooled load banks works together. The user interface screen shows for an individual load bank and the network control operation of that load bank that this load bank is in Group B the capacity of the entire group is 1500 kW that will have a total flow through the group of 3 load banks of 2248 liters per minute and the displayed parameters for this group is that 415 Volt AC is generally sense per leg of AC on that drew and each of the individual load banks that have a 500 kW rating are each contributing about 400 kW to the current validation test and that they are operating on an average of 60 Hertz. The group each is presented an average intake temperature of 30° C. between the three input temperature sensors into the three individual load banks working in network tandem for the three load banks have an average output temperature from the pressure vessel of 38° C. and the three load banks working in tandem have an average of a delta T temperature average of 8° C. dropped across the circulation heater (1). At the bottom of the user interface screen, a new load set point is set from 1200 kW, with each of the individual load banks supplying 400 kW, over to a new set point of 1000 kW on the user interface screen. The user interface screen shows that the operator has the ability to stop the validation process as well as an overall icon to apply the kW heat and/or electrical power draw with the group of network liquid-cooled load banks. Note, all the parameters shown on the digital display (9) are also recorded for verification records/auditing.

The programmable controller (8) has a software routine to control a master load on/off switch and a set of mechanical toggle switches that operate in manual mode controlled by the operator, automatic control mode controlled by the built in programmed controller, or remote control mode to allow harmonized operation of multiple liquid-cooled load bank units operate in parallel with optional toggle switch to switch to modes of operation. The programmable controller (8) has toggle switches for each load step. When in remote control, then the liquid-cooled load bank unit is controlled by an external programmable controller (8) such as a PLC, a laptop computer, etc. The remote toggle switch allows each load step electrical testing requirement to apply the same load simultaneously with multiple liquid-cooled load banks at once for “block loading.” Example: each liquid-cooled load bank applies 250 kW of load on each liquid-cooled load bank across four liquid-cooled load banks for a total of 1,000 kW. The programmable controller (8) on one of the liquid-cooled load banks is setting up the networked operations and controls the operators such that the contactors for the resistive heating elements within each of the four liquid-cooled load banks engage to apply their 250 kW of load within 16 milliseconds or less of each other. This simulates a real-world condition, for example, of power coming back online and an entire electrical system applying load at the same time. Note, the electrical load bank can use actual relays and contactors or use a SCR (Silicon Controlled Rectifiers) and SSR (Solid State Relays) to provide the electrical connection to engage the resistive heat load. An advantage of the SCRs and SSRs is that the window of time of all of the intended contactors to be engaged can be shortened/happen quicker on average in the SCRs and SSRs; and so, in networked operations, the full load being applied roughly simultaneously by all of the liquid-cooled load banks can happen even within a shorter time window of 16 milliseconds or less of each other. An advantage of the actual relays and contactors is that they are less susceptible to any permanent damage from higher amounts of instantaneous current draw across their contactors than the SCRs and SSRs; and thus, making testing larger kW capacity white rooms in a datacenter less of an issue when fewer liquid cooled load banks are networked and used to support that testing.

The user interface screen for network setup has icons to facilitate the creation of a networked group of liquid-cooled load banks to work together. The user interface screen for network control has icons and parameter displays to show how a networked group of liquid-cooled load banks works together. When, for example, 800 kW of load is needed, then two of the 500 kW liquid-cooled load banks are operated side by side so that both of them supply 400 kW. Both are networked to operate harmoniously with each other in parallel through the programmable controller (8) being in a group network mode. Again, when a white room in a datacenter that has 3,200 kilowatts of computing equipment, then the operator could use seven individual 500 kW liquid-cooled load banks, each cooperating with each other to supply roughly 460 kW of heat load and/or electrical power draw for a total of 3,200 kilowatts of simulated and replicated computing equipment.

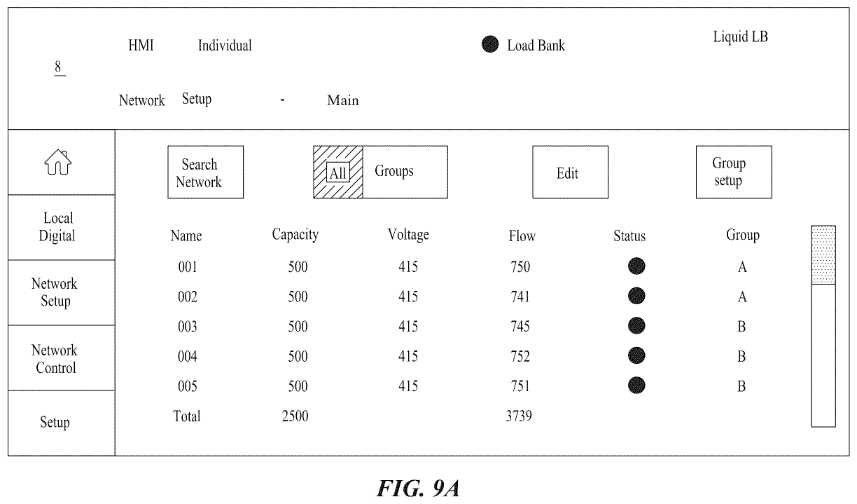

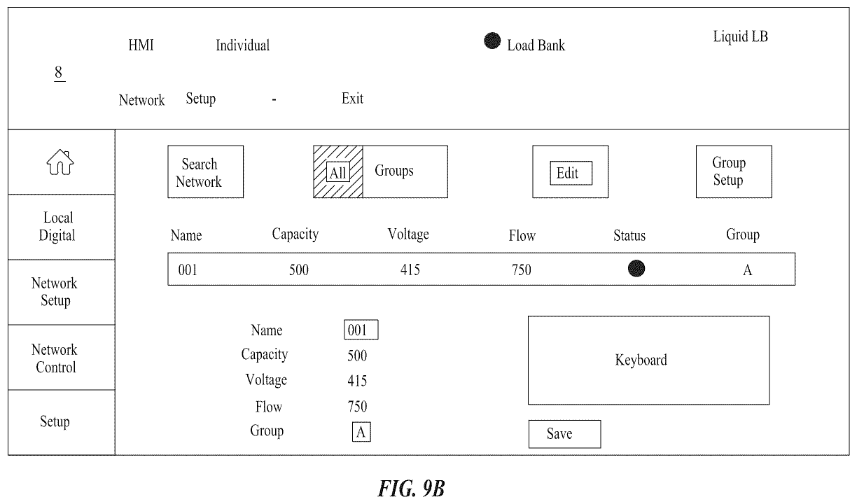

FIGS. 9A and 9B illustrate block diagrams of an embodiment of the programmable controller that has a user interface to cooperate with a digital display in order to display a local digital icon for a software routine to control individually the liquid-cooled load bank and a network control icon for another software routine to control a set of multiple networked liquid-cooled load banks cooperating in tandem with each other via a local digital screen on a particular liquid-cooled load bank as well as via an external input from a computing device connecting up to the particular liquid-cooled load bank.

The programmable controller (8) has a software routine to control individually the liquid-cooled load bank and another software routine to control a set of multiple networked liquid-cooled load banks cooperating in tandem with each other via a local digital screen on a particular liquid-cooled load bank as well as via an external input from a computing device connecting up to the particular liquid-cooled load bank.

The user interface screen for network setup has icons to facilitate the creation of a networked group of liquid-cooled load banks to work together. An individual liquid-cooled load bank designated as 001 in the network setup is being added to Group A. The operator/user can put in the capacity of the liquid-cooled load bank at 500 kW, the current voltage that the liquid-cooled load bank is operating at, which is 415 volts AC, and the flow rate that the liquid-cooled load bank is capable of—750 liters per minute. The digital display (9) will then display the operational status icons going across the screen allows the operator to search for available load banks and networks to add the individual load bank into, how to place it into a group of load banks, how to edit the particular group of load banks, and how to set up the group setup. The operator can operate a keyboard to add in additional information, but once they use the network setup user interface screen, then they can essentially add in or take out an individual liquid-cooled load bank into a network group of liquid-cooled load banks.

Another user interface screen for the network setup of multiple individual load banks shows that on this screen that the user has icons of search the network, display all liquid-cooled load bank groups, edit, and group setup of liquid-cooled load banks. The user interface shows the name assigned to individual liquid-cooled load banks with example names of 001, 002, 003, 004, and 005. Each of the liquid-cooled load banks has a capacity of 500 kW and a total capacity for the five individual load banks at 2500 kW total. The user interface of the digital display (9) shows that each of the individual liquid-cooled load banks is operating at 415 volts AC, and each of the individual five liquid-cooled load banks has an operational status of green. The flow rate through the liquid-cooled load bank designated 001 is 750 liters per minute. The flow rate through the individual liquid-cooled load bank designated 002 is 741 liters per minute. The flow rate through the individual liquid-cooled load bank designated 003 is 745 liters per minute. The flow rate through the individual liquid-cooled load banks designated as 004 is 752 liters per minute. The flow rate through the individual liquid-cooled load bank designated as 005 is currently 751 liters per minute. The user interface of the digital display (9) shows that the total flow rate through all five of the individual liquid-cooled load banks is 3739 liters per minute. The screen also shows that individual liquid-cooled load banks designated 001 and 002 have been put into and are controlled to work together in Group A. The screen also shows that the individual liquid-cooled load banks designated 003, 004, and 005 have been put into Group B to work together. In this example, Group A and Group B liquid-cooled load banks are being used to test a white room that has a capacity of approximately 2500 kW of computing equipment.

Referring back to FIGS. 1A and 1B, the liquid-cooled load bank is fully compliant with the open compute project guidelines for water-based transfer fluids in a single phase, cold plate-based liquid-cooled racks (e.g., no Zinc is in any component). The liquid-cooled load bank is constructed with 316 stainless steel and metal alloy components to mitigate the risk of chlorine crevice corrosion and/or other contamination issues, ensuring long-term durability in demanding heating and cooling environments.

The mechanical components in the mechanical load cell includes valves, piping, and the circulation heater (1), sensors, filter, etc., which are composed with 316 stainless steel or other similar metal alloy components, in order to mitigate a risk of corrosion and other contamination issues in order to be able i) to validate mechanical cooling systems that supply cooling fluid to sensitive computing equipment as well as ii) to be mechanically strong enough to maintain an integrity of the mechanical components when exposed to pressures of 50 PSI or greater. The sensitive computing equipment can have a technical water-cooling system of the building that will cool a liquid cooled server with small openings for liquid to flow to cool one or more chips in the liquid cooled server. Thus, the mechanical components—valves, piping, pressure vessel, sensors, filter, etc., in the liquid-cooled load bank exposed to the technical water cooling system of the building that will cool the actual computing equipment in the building are composed of 316 Stainless Steel and/or INCOLOY 800; rather than, a lower quality steel such as 304 stainless steel, which can corrode and cause clogging in the building cooling system if the corrosion in the testing fluid used for testing in the liquid-cooled load bank could transfer into the building's cooling system. In addition, the 316 Stainless Steel and/or INCOLOY 800 used in the mechanical components valves, piping, pressure vessel, sensors, filter, etc., in the liquid-cooled load bank; rather than, zinc or brass, prevents potential leaching of chlorine and/or other harmful chemicals into the building's cooling system from the Propylene glycol 25 in the liquid-cooled load bank, which could harm certain types of new chips used in computing equipment to satisfy requirements of the Open Compute Project and/or chloride can cause corrosion on steels such as 304 stainless. The 316 Stainless Steel & INCOLOY 800 are also structurally strong enough to maintain their integrity well passed the safety pressure relief valve set at 150 PSI.

The liquid-cooled load bank has verification components. The liquid-cooled load bank has advanced instrumentation and monitoring for parameters (e.g., power quality, voltage for each phase, current for each phase, inlet temperature, outlet temperature, delta T temperature, outlet pressure, inlet pressure, delta P pressure, flow rate, all with time stamps), which are both displayed on the display as well as stored in non-volatile memory so a validation report can later be generated. The user interface also allows the input of service level agreements to determine the commissioning tests as well as storage in the non-volatile memory to include in the validation report later generated. Electrically, the power quality measures kVA average from all three phases of the AC times a power factor, and when a pure resistive load exists, then a unity power factor exists; and thus, kVA=kW. The liquid-cooled load bank has multiple instruments and data monitoring equipment to provide precise mechanical and electrical measurements that enable a building, such as a datacenter, to be validated against their service level agreements (SLAs). The mechanical parameters that are monitored and displayed include features such as input and output fluid temperature, input and output fluid pressure, and the fluid flow rate through the liquid-cooled load bank. The liquid-cooled load bank has a large amount of memory storage to store all of the validation and commissioning data. The liquid-cooled load bank produces detailed logs and accurate logs with timing, including timestamps, sample rates, and other things, captured from the sensors and the programmable controller (8) that can be included in a produced report so that the building can be commissioned. All of this high-fidelity data is not only shown on a digital display (9) but also recorded in a time series so that the data can be reliably validated to help with the system's testing and having facilities meet their operational and reliability commitments.

### Computing Systems

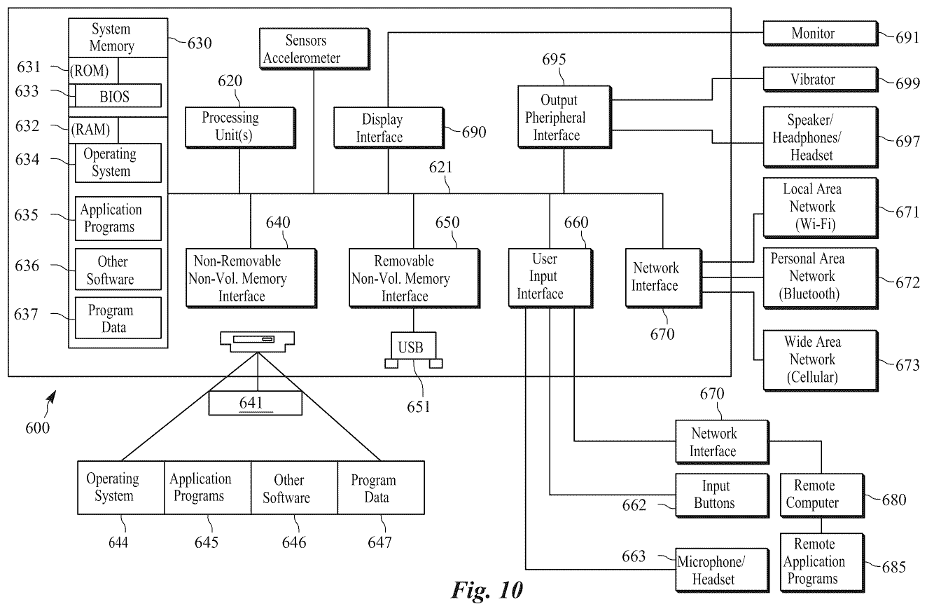

FIG. 10 illustrates a diagram of an embodiment of a computing device that can be a part of the systems associated with the liquid-cooled load bank and programmable controller discussed herein. The computing device 600 may include one or more processors or processing units 620 to execute instructions, one or more memories 630-632 to store information, one or more data input components 660-663 to receive data input from a user of the computing device 600, one or more modules that include the management module, a network interface communication circuit 670 to establish a communication link to communicate with other computing devices external to the computing device, one or more sensors where an output from the sensors is used for sensing a specific triggering condition and then correspondingly generating one or more preprogrammed actions, a display screen 691 to display at least some of the information stored in the one or more memories 630-632 and other components. Note, portions of this system that are implemented in software 644, 645, 646 may be stored in the one or more memories 630-632 and are executed by the one or more processors 620.

As discussed, the device and its associated modules, the generated models and the machine learning architecture, and the EDA tools can be implemented with aspects of the computing device. The modules and/or models can work with one or more processors to execute instructions and a memory to store data and instructions.

The system memory 630 includes computer storage media in the form of volatile and/or nonvolatile memory such as read-only memory (ROM) 631 and random access memory (RAM) 632. These computing machine-readable media can be any available media that can be accessed by computing system 600. By way of example, and not limitation, computing machine-readable media use includes storage of information, such as computer-readable instructions, data structures, other executable software, or other data. Computer-storage media includes, but is not limited to, RAM, ROM, EEPROM, flash memory or other memory technology, CD-ROM, digital versatile disks (DVD) or other optical disk storage, magnetic cassettes, magnetic tape, magnetic disk storage or other magnetic storage devices, or any other tangible medium which can be used to store the desired information and which can be accessed by the computing device 600. Transitory media such as wireless channels are not included in the machine-readable media. Communication media typically embody computer readable instructions, data structures, other executable software, or other transport mechanism and includes any information delivery media.

The system further includes a basic input/output system 633 (BIOS) containing the basic routines that help to transfer information between elements within the computing system 600, such as during start-up, is typically stored in ROM 631. RAM 632 typically contains data and/or software that are immediately accessible to and/or presently being operated on by the processing unit 620. By way of example, and not limitation, the RAM 632 can include a portion of the operating system 634, application programs 635, other executable software 636, and program data 637.

The computing system 600 can also include other removable/non-removable volatile/nonvolatile computer storage media. By way of example only, the system has a solid-state memory 641. The solid-state memory 641 is typically connected to the system bus 621 through a non-removable memory interface such as interface 640, and USB drive 651 is typically connected to the system bus 621 by a removable memory interface, such as interface 650.

A user may enter commands and information into the computing system 600 through input devices such as a keyboard, touchscreen, or software or hardware input buttons 662, a microphone 663, a pointing device and/or scrolling input component, such as a mouse, trackball or touch pad. These and other input devices are often connected to the processing unit 620 through a user input interface 660 that is coupled to the system bus 621, but can be connected by other interface and bus structures, such as a parallel port, game port, or a universal serial bus (USB). A display monitor 691 or other type of display screen device is also connected to the system bus 621 via an interface, such as a display interface 690. In addition to the monitor 691, computing devices may also include other peripheral output devices such as speakers 697, a vibrator 699, and other output devices, which may be connected through an output peripheral interface 695.

The computing system 600 can operate in a networked environment using logical connections to one or more remote computers/client devices, such as a remote computing system 680. The remote computing system 680 can a personal computer, a mobile computing device, a server, a router, a network PC, a peer device, or other common network node, and typically includes many or all of the elements described above relative to the computing system 600. The logical connections can include a personal area network (PAN) 672 (e.g., Bluetooth®), a local area network (LAN) 671 (e.g., Wi-Fi), and a wide area network (WAN) 673 (e.g., cellular network), but may also include other networks such as a personal area network (e.g., Bluetooth®). Such networking environments are commonplace in offices, enterprise-wide computer networks, intranets, and the Internet. A browser application may be resonant on the computing device and stored in the memory.

When used in a LAN networking environment, the computing system 600 is connected to the LAN 671 through a network interface 670, which can be, for example, a Bluetooth® or Wi-Fi adapter. When used in a WAN networking environment (e.g., Internet), the computing system 600 typically includes some means for establishing communications over the WAN 673. With respect to mobile telecommunication technologies, for example, a radio interface, which can be internal or external, can be connected to the system bus 621 via the network interface 670, or other appropriate mechanism. In a networked environment, other software depicted relative to the computing system 600, or portions thereof, may be stored in the remote memory storage device. By way of example, and not limitation, the system has remote application programs 685 as residing on remote computing device 680. It will be appreciated that the network connections shown are examples and other means of establishing a communications link between the computing devices that may be used.

As discussed, the computing system 600 can include mobile devices with a processing unit 620, a memory (e.g., ROM 631, RAM 632, etc.), a built in battery to power the computing device, an AC power input to charge the battery, a display screen, a built-in Wi-Fi circuitry to wirelessly communicate with a remote computing device connected to network.

It should be noted that the present design can be carried out on a computing system such as that described with respect to shown herein. However, the present design can be carried out on a server, a computing device devoted to message handling, or on a distributed system in which different portions of the present design are carried out on different parts of the distributed computing system.

In some embodiments, software used to facilitate algorithms discussed herein can be embedded onto a non-transitory machine-readable medium. A machine-readable medium includes any mechanism that stores information in a form readable by a machine (e.g., a computer). For example, a non-transitory machine-readable medium can include read-only memory (ROM); random access memory (RAM); magnetic disk storage media; optical storage media; flash memory devices; Digital Versatile Disc (DVD's), EPROMs, EEPROMs, FLASH memory, magnetic or optical cards, or any type of media suitable for storing electronic instructions.

Note, an application described herein includes but is not limited to software applications, mobile applications, and programs that are part of an operating system application. Some portions of this description are presented in terms of algorithms and symbolic representations of operations on data bits within a computer memory. These algorithmic descriptions and representations are the means used by those skilled in the data processing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like. These algorithms can be written in a number of different software programming languages such as C, C+, HTTP, Java, Python, or other similar languages. Also, an algorithm can be implemented with lines of code in software, configured logic gates in software, or a combination of both. In an embodiment, the logic consists of electronic circuits that follow the rules of Boolean Logic, software that contain patterns of instructions, or any combination of both. Any portions of an algorithm implemented in software can be stored in an executable format in portion of a memory and is executed by one or more processors. In an embodiment, a module can be implemented with electronic circuits, software being stored in a memory and executed by one or more processors, and any combination of both.

It should be borne in mind, however, that all of these and similar terms are to be associated with the appropriate physical quantities and are merely convenient labels applied to these quantities. Unless specifically stated otherwise as apparent from the above discussions, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers, or other such information storage, transmission or display devices.

Many functions performed by electronic hardware components can be duplicated by software emulation. Thus, a software program written to accomplish those same functions can emulate the functionality of the hardware components in input-output circuitry.

References in the specification to “an embodiment,” “an example”, etc., indicate that the embodiment or example described may include a particular feature, structure, or characteristic, but every embodiment may not necessarily include the particular feature, structure, or characteristic. Such phrases can be not necessarily referring to the same embodiment. Further, when a particular feature, structure, or characteristic is described in connection with an embodiment, it is believed to be within the knowledge of one skilled in the art to affect such feature, structure, or characteristic in connection with other embodiments whether or not explicitly indicated.

While the foregoing design and embodiments thereof have been provided in considerable detail, it is not the intention of the applicant(s) for the design and embodiments provided herein to be limiting. Additional adaptations and/or modifications are possible, and, in broader aspects, these adaptations and/or modifications are also encompassed. Accordingly, departures may be made from the foregoing design and embodiments without departing from the scope afforded by the following claims, which scope is only limited by the claims when appropriately construed.

What is claimed is:

1. An apparatus, comprising:
a liquid-cooled load bank configured to contain an electrical load cell and a mechanical load cell to test and validate an electrical system with an electrical load and a mechanical system by heating a testing fluid in a circulation heater in the mechanical load cell and cooling of the mechanical load cell with the mechanical system in a building to validate the electrical system and the mechanical system of the building during a commissioning of the building;
a programmable controller housed in the liquid-cooled load bank configured to control electrical power draw by the electrical load cell and to control the heating of the testing fluid through the mechanical load cell to allow control over parameters including a delta T temperature rise across the mechanical load cell, a delta P pressure drop across the mechanical load cell, and a flow rate through the mechanical load cell, where the parameters of the delta T temperature rise, the delta P pressure drop, and the flow rate replicate and simulate characteristics corresponding to a set of computing equipment that the electrical system and the mechanical system of the building will be required to support after the commissioning of the building; and
where the programmable controller has a user interface to cooperate with a digital display to display the parameters, where any software instructions in the programmable controller are stored in one or more non-transitory storage mediums in an executable format to be executed by one or more processors.

2. The apparatus of claim 1, where software routines in the programmable controller, the mechanical load cell, and the electrical load cell of the liquid-cooled load bank are specifically configured to facilitate the commissioning of the mechanical system independent of the electrical system in the building but also to facilitate validation of both the mechanical system and the electrical system simultaneously at a same time with each other.

3. The apparatus of claim 1, where the programmable controller has a first software routine to control individually the liquid-cooled load bank and a second software routine to control a set of multiple networked liquid-cooled load banks cooperating in tandem with each other via a local digital screen on a first liquid-cooled load bank as well as via an external input from a computing device connecting up to the first liquid-cooled load bank,
where the digital display cooperating with the programmable controller has a first section to display parameters associated with the electrical load cell being monitored, and
where the digital display cooperating with the programmable controller has a second section to display parameters associated with the mechanical load cell being monitored.

4. The apparatus of claim 1, where the electrical load cell in the liquid-cooled load bank has a series of resistive elements in an electrical arrangement to allow the electrical power draw to be set and increased in fixed increments of a total electrical power draw that the electrical load cell is capable of replicating and simulating, and where each of the resistive elements has a relay that can be triggered by input from the programmable controller as well as by a set of local manual switches on a front of a housing of the liquid-cooled load bank.

5. The apparatus of claim 1, where mechanical components in the mechanical load cell includes valves, piping, and the circulation heater, are composed with 316 stainless steel or other similar metal alloy components to mitigate a risk of corrosion and other contamination issues to be able i) to validate mechanical cooling systems that supply cooling fluid to sensitive computing equipment as well as ii) to be mechanically strong enough to maintain an integrity of the mechanical components when exposed to pressures of 50 PSI or greater.

6. The apparatus of claim 1, further comprising:
a housing of the liquid-cooled load bank constructed to have electrical connections on its external surface to support a power input between 415V AC and 480V AC three phase across resistive heating elements in the circulation heater of the mechanical load cell as well as a control power transformer to tap off any of a 480 volts input or a 415 volt input in order to supply a 120 VAC control power to use on electrical equipment in the liquid-cooled load bank.

7. The apparatus of claim 1, where the programmable controller is configured to select different arrangements of resistive heating elements in the circulation heater of the mechanical load cell and reference a heating up table and an amount of energy added to a volume of water flowing through a pressure vessel of the circulation heater in the mechanical load cell to calculate and create a specific rate of heat increase for the testing fluid flowing through the circulation heater.

8. The apparatus of claim 1, where the mechanical load cell in the liquid-cooled load bank has the circulation heater with a pressure vessel, a pressure control valve, an inlet valve, a return valve, an input pressure sensor, an outlet pressure sensor, an input temperature sensor, a flow rate sensor, and an outlet temperature sensor.

9. The apparatus of claim 1, where the programmable controller is configured to receive input from an input pressure sensor, a flow sensor, an input temperature sensor, an output pressure sensor, and an output temperature sensor, then to send inputs into a pressure control valve and heating elements in the circulation heater according to a software routine in the programmable controller to control how open the pressure control valve will be and a power draw by the heating elements in light of a feedback loop from each of the sensors in order to satisfy one or more parameter set points inputted by an operator.

10. The apparatus of claim 1, where the programmable controller is configured to control an operation of a pressure control valve in the mechanical load cell and a set of resistive heating elements in an electrical arrangement in the mechanical load cell to coordinate together in order to match a design criteria including the delta T temperature rise across the mechanical load cell, the delta P pressure drop across the mechanical load cell, and the flow rate through the mechanical load cell for multiple different computing equipment types that can be installed in the building in order to replicate and simulate exact characteristics corresponding to the set of computing equipment that the mechanical system of the building will be required to support after the commissioning of the building.

11. A method to test, comprising:
configuring a liquid-cooled load bank to contain an electrical load cell and a mechanical load cell to test and validate an electrical system with an electrical load and a mechanical system by heating a testing fluid in a circulation heater in the mechanical load cell and cooling of the mechanical load cell with the mechanical system in a building to validate the electrical system and the mechanical system of the building during a commissioning of the building;
configuring a programmable controller housed in the liquid-cooled load bank to control electrical power draw by the electrical load cell and to control the heating of the testing fluid through the mechanical load cell to allow control over parameters including a delta T temperature rise across the mechanical load cell, a delta P pressure drop across the mechanical load cell, and a flow rate through the mechanical load cell, where the parameters of the delta T temperature rise, the delta P pressure drop, and the flow rate replicate and simulate characteristics corresponding to a set of computing equipment that the electrical system and the mechanical system of the building will be required to support after the commissioning of the building; and
configuring the programmable controller to have a user interface to cooperate with a digital display to display the parameters.

12. The method of claim 11, further comprising:
configuring software routines in the programmable controller, the mechanical load cell, and the electrical load cell of the liquid-cooled load bank to facilitate the commissioning of the mechanical system independent of the electrical system in the building but also to facilitate validation of both the mechanical system and the electrical system simultaneously at a same time with each other.

13. The method of claim 11, further comprising:
configuring the programmable controller to have a first software routine to control individually the liquid-cooled load bank and a second software routine to control a set of multiple networked liquid-cooled load banks cooperating in tandem with each other via a local digital screen on a first liquid-cooled load bank as well as via an external input from a computing device connecting up to the first liquid-cooled load bank,
configuring the digital display to cooperate with the programmable controller to use a first section to display parameters associated with the electrical load cell being monitored, and
configuring the digital display to cooperate with the programmable controller to use a second section to display parameters associated with the mechanical load cell being monitored.

14. The method of claim 11, further comprising:
configuring the electrical load cell in the liquid-cooled load bank to have a series of resistive elements in an electrical arrangement to allow the electrical power draw to be set and increased in fixed increments of a total electrical power draw that the electrical load cell is capable of replicating and simulating, and
configuring each of the resistive elements to have a relay that can be triggered by input from the programmable controller as well as by a set of local manual switches on a front of a housing of the liquid-cooled load bank.

15. The method of claim 11, further comprising:
configuring mechanical components in the mechanical load cell including valves, piping, and the circulation heater, to be constructed with 316 stainless steel or other similar metal alloy components to mitigate a risk of corrosion and other contamination issues to be able i) to validate mechanical cooling systems that supply cooling fluid to sensitive computing equipment as well as ii) to be mechanically strong enough to maintain an integrity of the mechanical components when exposed to pressures of 50 PSI or greater.

16. The method of claim 1, further comprising:
configuring a housing of the liquid-cooled load bank to have electrical connections on its external surface to support a power input between 415V AC and 480V AC three phase across resistive heating elements in the circulation heater of the mechanical load cell as well as a control power transformer to tap off any of a 480 volts input or a 415 volt input in order to supply a 120 VAC control power to use on electrical equipment in the liquid-cooled load bank.

17. The method of claim 11, further comprising:
configuring the programmable controller to select different arrangements of resistive heating elements in the circulation heater of the mechanical load cell and reference a heating up table and an amount of energy added to a volume of water flowing through a pressure vessel of the circulation heater in the mechanical load cell to accurately calculate and create a specific rate of heat increase for the testing fluid flowing through the circulation heater.

18. The method of claim 11, further comprising:
configuring the mechanical load cell in the liquid-cooled load bank to have the circulation heater with a pressure vessel, a pressure control valve, an inlet valve, a return valve, an input pressure sensor, an outlet pressure sensor, an input temperature sensor, a flow rate sensor, and an outlet temperature sensor.

19. The method of claim 11, further comprising:
configuring the programmable controller to receive input from an input pressure sensor, a flow sensor, an input temperature sensor, an output pressure sensor, and an output temperature sensor, then to send inputs into a pressure control valve and heating elements in the circulation heater according to a software routine in the programmable controller to control how open the pressure control valve will be and a power draw by the heating elements in light of a feedback loop from each of the sensors in order to satisfy one or more parameter set points inputted by an operator.

20. The method of claim 11, further comprising:
configuring the programmable controller to control an operation of a pressure control valve in the mechanical load cell and a set of resistive heating elements in an electrical arrangement in the mechanical load cell to coordinate together in order to match a design criteria including the delta T temperature rise across the mechanical load cell, the delta P pressure drop across the mechanical load cell, and the flow rate through the mechanical load cell for multiple different computing equipment types that can be installed in the building in order to replicate and simulate exact characteristics corresponding to the set of computing equipment that the mechanical system of the building will be required to support after the commissioning of the building.
